(19) United States
(12) Patent Application Publication
(10) Pub. No.: US 2024/0421137 A1
(43) Pub. Date: Dec. 19, 2024

(54) CHIP PACKAGE UNIT, CHIP PACKAGE STACK MODULE, AND METHOD OF MANUFACTURING CHIP PACKAGE STACK MODULE

(71) Applicant: WALTON ADVANCED ENGINEERING, INC., KAOHSIUNG (TW)

(72) Inventors: HONG-CHI YU, KAOHSIUNG (TW); CHUN-JUNG LIN, KAOHSIUNG (TW); RUEI-TING GU, KAOHSIUNG (TW)

(21) Appl. No.: 18/645,411

(22) Filed: Apr. 25, 2024

(30) Foreign Application Priority Data
Jun. 16, 2023 (TW) 112122656

(51) Int. Cl. H01L 25/10; H01L 23/31; H01L 23/498; H01L 25/00; H10B 80/00

(52) U.S. Cl. CPC H01L 25/105; H01L 23/3107; H01L 23/49816; H01L 23/49827; H01L 25/50; H10B 80/00; H01L 2225/1023; H01L 2225/1058

(57) ABSTRACT

A chip package unit, a chip package stack module, and a method of manufacturing the chip package stack module are provided. The chip package stack module includes upper and lower chip package units stacked vertically. The chip package unit includes a plurality of conductive pillars each of which has an upper pad and a lower pad respectively on upper and lower ends of the conductive pillar. The upper and lower chip package units are stacked by the lower pads of the upper chip package unit and the upper pads of the lower chip package unit electrically connected with each other. The conductive pillars of the upper chip package unit are electrically connected with the conductive pillars of the lower chip package unit correspondingly so that a memory chip of the upper chip package unit and a memory chip of the lower chip package unit are electrically connected.

### CROSS-REFERENCE TO RELATED APPLICATIONS

This non-provisional application claims priority under 35 U.S.C. § 119(a) on Patent Application No(s). 112122656 filed in Taiwan, R.O.C. on Jun. 16, 2023, the entire contents of which are hereby incorporated by reference.

### BACKGROUND OF THE INVENTION

The present invention relates to a chip package unit, a chip package stack module, and a method of manufacturing the chip package stack module, especially to a chip package unit in which conductive pillars are embedded and produced by simplified manufacturing process, a chip package stack module, and a method of manufacturing the chip package stack module.

As to memory technique in semiconductors, at least two chips are stacked for expansion of memory function/capacity. In such chip stacking technique, the chips are first stacked to form a chip stack by molding. However, the whole chip stack needs to be replaced or repaired once there is one defect chip in the chips stacked. Thus the production cost for manufacturers is increased and this is not good for mass production. In order to solve the above problems, certain techniques use a plurality of chip package units already molded to form the chip stack such as stacking techniques provided in U.S. Pat. No. 9,685,429 B2 (equivalent patents including Chinese Pat. No. 204885152 U and Taiwanese Pat. No. M509421), and U.S. Pat. No. 8,502,378 B2 (equivalent patents including Taiwanese Pat. No. 1501365). Thereby production cost and quality control cost for manufacturers are reduced and products are getting easier to be mass-produced.

However, the above technique still has certain shortcomings. For example, conductive pillars of the chip package stack module in the U.S. Pat. No. 9,685,429 B2 is exposed and located outside an insulation layer, not integrally molded together with the chip. Thus the conductive pillar is easy to get damaged and further result in poor yield rate of final products. Moreover, as to conductive pillars in a chip package stack module revealed in the U.S. Pat. No. 8,502,378 B2 are embedded in the insulation layer. Yet the conductive pillar is formed by connection of two different conductive pins produced by two different manufacturing processes. Thus the manufacturing processes are complicated and this has negative effects on cost reduction in manufacturing.

### SUMMARY OF THE INVENTION

Therefore, it is a primary object of the present invention to provide a chip package unit, a chip package stack module, and a method of manufacturing the chip package stack module. The chip package stack module includes at least two chip package units which are adjacent to each other and stacked vertically with respect to each other. The respective chip package units include a plurality of conductive pillars each of which is provided with an upper pad and a lower pad respectively on an upper end and a lower end of the conductive pillar. The upper chip package unit is stacked over the lower chip package unit by the lower pads of the upper chip package unit and the upper pads of the lower chip package unit electrically connected and coupled with each other. The conductive pillars of the upper chip package unit are electrically connected with the conductive pillars of the lower chip package unit correspondingly so that a memory chip of the upper chip package unit and a memory chip of the lower chip package unit are electrically connected. Thereby problems of products of the stack module available now including poor yield rate caused by easy damages of conductive pillars exposed and complicated manufacturing processes can be solved.

In order to achieve the above object, a chip package unit according to the present invention is composed of a substrate, a patterned circuit layer, at least one memory chip, an insulation layer, a plurality of through holes, and a plurality of conductive pillars. The patterned circuit layer is disposed on a surface of the substrate and the memory chip is electrically coupled to the patterned circuit layer by flip chip technology. The insulation layer is covering not only the substrate but also a gap between the substrate and the memory chips. The respective through holes are vertically penetrating the substrate and the insulation layer and arranged at a preset fixed position around the memory chip. The conductive pillars are formed in the through holes correspondingly while an upper end and a lower end of each of the conductive pillars are respectively provided with an upper pad and a lower pad. The memory chip is electrically connected with the respective conductive pillars by the patterned circuit layer and further electrically connected with the outside by the upper pads or the lower pads of the conductive pillar.

A chip package stack module according to the present invention includes at least two chip package units which are adjacent to each other and stacked vertically with respect to each other to form the upper chip package unit and the lower chip package unit. Each of the chip package units consists of a substrate, a patterned circuit layer, at least one memory chip, an insulation layer, a plurality of through holes, and a plurality of conductive pillars. A lower pad of the upper chip package unit and an upper pad of the lower chip package unit are aligned with each other vertically. The upper chip package unit is stacked over the lower chip package unit by the lower pads of the upper chip package unit and the upper pads of the lower chip package unit electrically connected and coupled with each other. The conductive pillar of the upper chip package unit is electrically connected with the conductive pillar of the lower chip package unit correspondingly so that the memory chip of the upper chip package unit is electrically connected with the memory chip of the lower chip package unit.

Preferably, the chip package stack module further includes at least one solder ball which is disposed on the lower pad of the lowest chip package unit among the respective chip package units.

The chip package stack module is further mounted to a printed circuit board (PCB).

A method of manufacturing the above chip package stack module according to the present invention includes the following steps. Step S1: providing the at least two chip package units. Step S2: arranging the two chip package units vertically at an upper position and a lower position to form the upper chip package unit and the lower chip package unit adjacent to each other while the lower pads of the upper chip package unit and the upper pads of the lower chip package unit are aligned with each other vertically and corresponding to each other. Step S3: stacking the upper chip package unit over the lower chip package unit to form the chip package stack module by the lower pads of the upper chip package unit and the upper pads of the lower chip package unit electrically connected and coupled with each other. Thereby the chip package stack module with the above design can be mass-produced.

### BRIEF DESCRIPTION OF THE DRAWINGS

FIG. 1 is a side sectional view of a chip package stack module which includes two chip package units therein according to the present invention;

FIG. 2 is a side sectional view of a chip package unit according to the present invention;

FIG. 3 is a schematic drawing showing an exploded view of the embodiment in FIG. 1 according to the present invention;

FIG. 4 is a schematic drawing showing an exploded view of the embodiment in FIG. 1 further stacked with a chip package unit according to the present invention;

FIG. 5 is a side sectional view of a chip package stack module which includes three chip package units therein according to the present invention.

### DETAILED DESCRIPTION OF THE PREFERRED EMBODIMENT

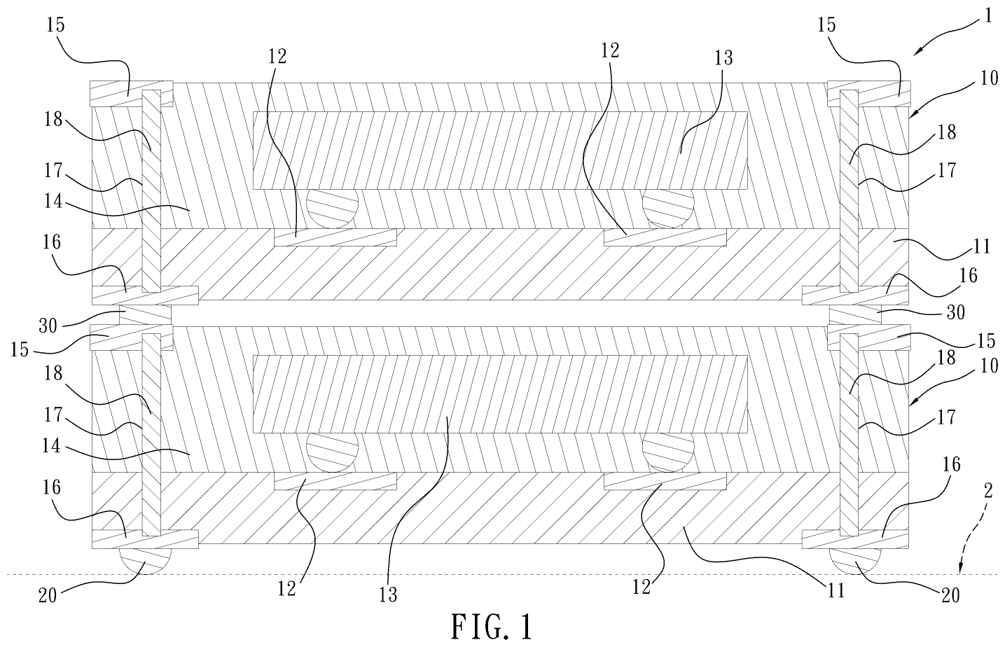

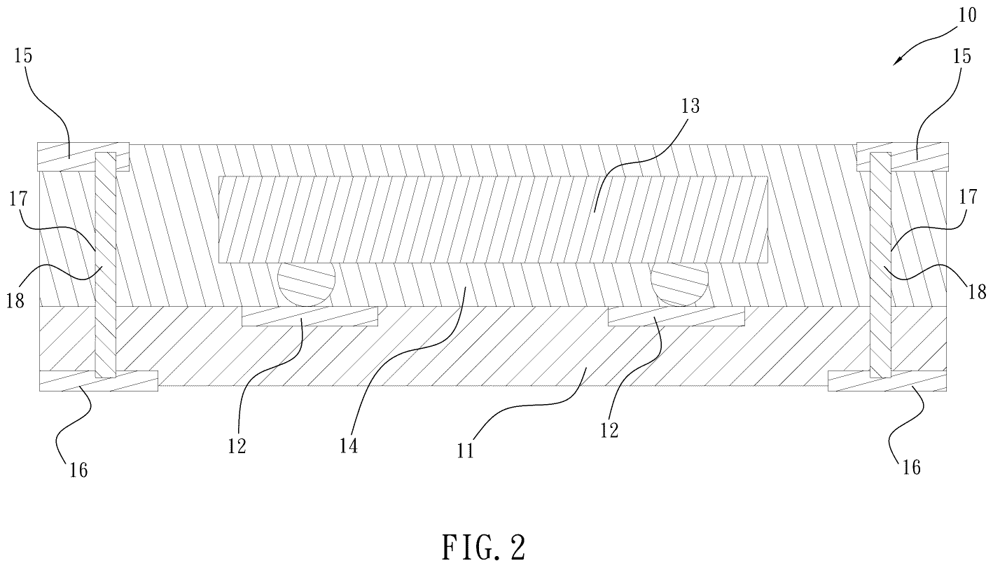

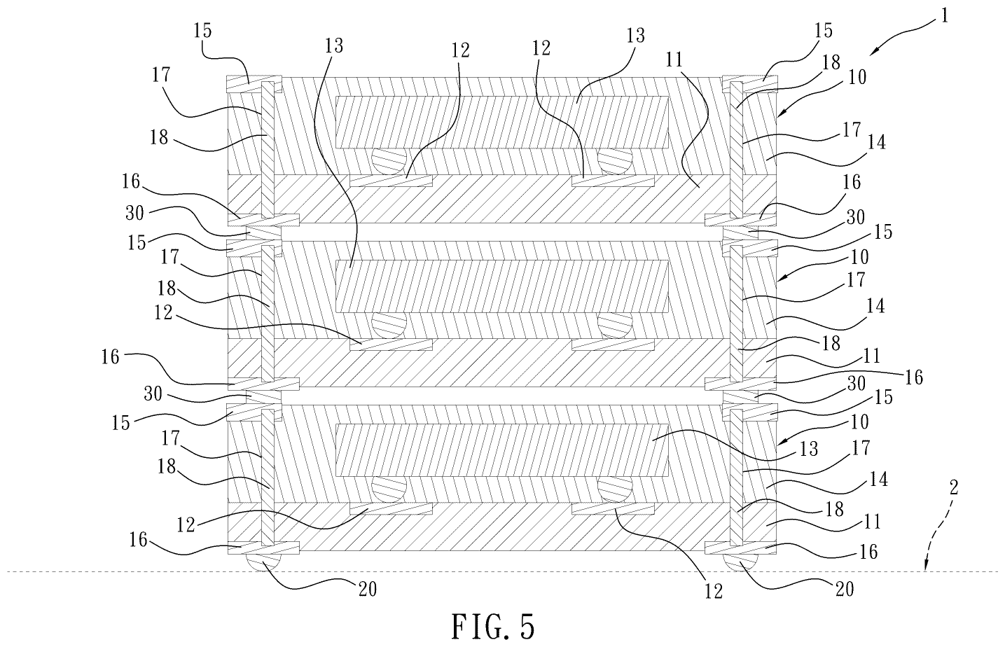

Refer to FIG. 1 and FIG. 5, a chip package stack module 1 according to the present invention includes at least two chip package units 10 which are adjacent to each other and stacked vertically with respect to each other to form the upper chip package unit 10 and the lower chip package unit 10. Each of the chip package units 10 consists of a substrate 11, a patterned circuit layer 12, at least one memory chip 13, an insulation layer 14, a plurality of through holes 17, and a plurality of conductive pillars 18, as shown in FIG. 2.

Refer to FIG. 2, the patterned circuit layer 12 is disposed on a surface of the substrate 11 and the memory chip 13 is electrically coupled to the patterned circuit layer 12 by flip chip technology. The insulation layer 14 is covering not only the substrate 11 but also a gap between the substrate 11 and the memory chip 13. The respective through holes 17 are vertically penetrating the substrate 11 and the insulation layer 14 and arranged at a preset fixed position around the memory chip 13. The respective through holes 17 can be formed by laser drilling, mechanical drilling, or etching drilling, but not limited. The respective conductive pillars 18 are formed in the corresponding through holes 17 while an upper end and a lower end of each of the conductive pillars 18 are respectively provided with an upper pad 15 and a lower pad 16. The memory chip 13 is electrically connected with the respective conductive pillars 18 by the patterned circuit layer 12 and further electrically connected with the outside by the upper pads 15 or the lower pads 16 of the conductive pillar 18.

Refer to FIG. 1 and FIG. 5, the lower pads 16 of the upper chip package unit 10 is corresponding to and located over the upper pads 15 of the lower chip package unit 10. The upper chip package unit 10 is stacked over the lower chip package unit 10 by the lower pads 16 of the upper chip package unit 10 and the upper pads 15 of the lower chip package unit 10 electrically connected and coupled with each other. The conductive pillars 18 of the upper chip package unit 10 are electrically connected with the conductive pillars 18 of the lower chip package unit 10 correspondingly so that the memory chip 13 of the upper chip package unit 10 is electrically connected with the memory chip 13 of the lower chip package unit 10 for expanding memory function/capacity.

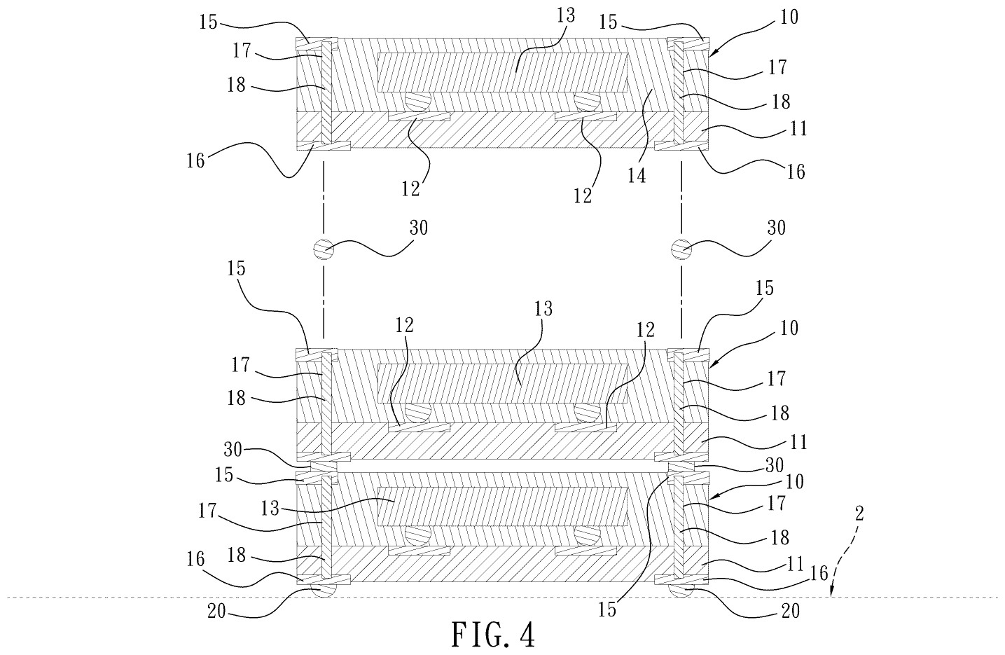

Refer to FIG. 4 and FIG. 5, the number of the chip package units 10 of the chip package stack module 1 is three, but not limited. Such arrangement is beneficial to expansion of memory function/capacity.

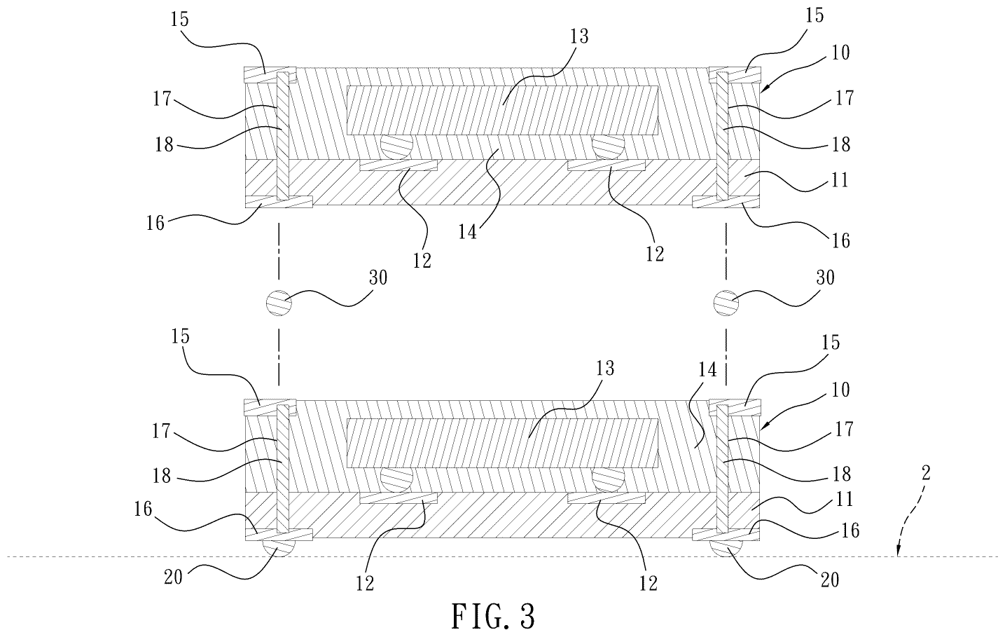

Refer to FIG. 1, FIG. 3, and FIG. 5, in the chip package stack module 1, a conductive metal 30 is further provided between the lower pad 16 of the upper chip package unit 10 and the upper pad 15 of the lower chip package unit 10, but not limited. Thus the lower pad 16 and the upper pad 15 are connected by the conductive metal 30 after reflow and connection strength is significantly increased.

Refer to FIG. 1, and FIG. 5, the chip package stack module 1 further includes at least one solder ball 20 which is disposed on the lower pad 16 of the lowest chip package unit 10 among the respective chip package units 10.

Refer to FIG. 1, and FIG. 5, the chip package stack module 1 is further mounted to a printed circuit board (PCB) 2, but not limited. The chip package stack module 1 is applied to fan-out in the PCB (FOIP), but not limited.

Refer to FIG. 1, FIG. 3, and FIG. 5, a method of manufacturing the chip package stack module 1 according to the present invention includes the following steps.
Step S1: providing at least two the chip package units 10;
Step S2: arranging the two chip package units 10 vertically at an upper position and a lower position to form the upper chip package unit 10 and the lower chip package unit 10 adjacent to each other while the lower pads 16 of the upper chip package unit 10 and the upper pads 15 of the lower chip package unit 10 are aligned with each other vertically and correspondingly;
Step S3: stacking the upper chip package unit 10 over the lower chip package unit 10 to form the chip package stack module 1 by the lower pads 16 of the upper chip package unit 10 and the upper pads 15 of the lower chip package unit 10 electrically connected and coupled with each other, as shown in FIG. 1 and FIG. 5.

Compared with the stack module available now, the chip package stack module 1 according to the present invention has the following advantages.
(1) As shown in FIG. 2, the through hole 17 is penetrating the substrate 11 and the insulation layer 14 and arranged at a preset fixed position around the memory chip 13 while the conductive pillar 18 is formed in the corresponding through hole 17. Thus the problem of the stack module available now with poor yield rate caused by easy damages of conductive pillars located outside the insulation layer and exposed can be solved.
(2) The conductive pillar 18 is vertically penetrating the substrate 11 and the insulation layer 14 and formed in the chip package unit 10. Thus a problem of complicated manufacturing process caused by two different manufacturing processes used for production of two conductive pillars connected with each other in the stack module available now can be solved.
(3) During the method of manufacturing the chip package stack module 1 according to the present invention, the two adjacent chip package units 10 are arranged vertically to each other to form the upper chip package unit 10 and the lower chip package unit 10. The lower pads 16 of the upper chip package unit 10 and the upper pads 15 of the lower chip package unit 10 are aligned with each other vertically and correspondingly, as shown in FIG. 3 and FIG. 4. Thereby the chip package units 10 are stacked more precisely with each other and this helps improve stacking efficiency for manufacturers.

1. A chip package unit comprising:
a substrate;
a patterned circuit layer disposed on a surface of the substrate;
at least one memory chip electrically coupled to the patterned circuit layer by flip chip technology;
an insulation layer covering the substrate and a gap between the substrate and the memory chip;
a plurality of through holes each of which is vertically penetrating the substrate and the insulation layer and arranged at a preset fixed position around the memory chip; and
a plurality of conductive pillars each of which is formed in the through hole correspondingly and having an upper end and a lower end respectively provided with an upper pad and a lower pad opposite to each other;
wherein the memory chip is electrically connected with the respective conductive pillars by the patterned circuit layer and further electrically connected with the outside by the upper pads or the lower pads of the conductive pillars.

2. A chip package stack module comprising:
at least two chip package units each of which is the chip package unit as claimed in claim 1; the two chip package units adjacent to each other and stacked vertically to form the upper chip package unit and the lower chip package unit;
wherein the lower pads of the upper chip package unit and the upper pads of the lower chip package unit are corresponding to each other vertically; wherein the upper chip package unit is stacked over the lower chip package unit by the lower pads of the upper chip package unit and the upper pads of the lower chip package unit electrically connected and coupled with each other; wherein the conductive pillars of the upper chip package unit are electrically connected with the conductive pillars of the lower chip package unit correspondingly so that the memory chip of the upper chip package unit is electrically connected with the memory chip of the lower chip package unit.

3. The chip package stack module as claimed in claim 2, wherein the chip package stack module further includes at least one solder ball which is disposed on the lower pad of the lowest chip package unit among the chip package units.

4. The chip package stack module as claimed in claim 2, wherein the chip package stack module is further mounted to a printed circuit board (PCB).

5. A method of manufacturing chip package stack modules comprising the steps of:
Step S1: providing at least two chip package units each of which is as the chip package unit claimed in claim 1;
Step S2: arranging the two chip package units vertically at an upper position and a lower position to form the upper chip package unit and the lower chip package unit adjacent to each other; the lower pads of the upper chip package unit and the upper pads of the lower chip package unit being aligned with each other vertically and corresponding to each other;
Step S3: stacking the upper chip package unit over the lower chip package unit to form the chip package stack module by the lower pads of the upper chip package unit and the upper pads of the lower chip package unit electrically connected and coupled with each other.
